(19) United States
(12) Patent Application Publication
(10) Pub. No.: US 2026/0142625 A1
(43) Pub. Date: May 21, 2026

(54) PROTECTION CIRCUIT

(71) Applicant: Murata Manufacturing Co., Ltd., Nagaokakyo-shi (JP)

(72) Inventor: Shohei IMAI, Nagaokakyo-shi (JP)

(21) Appl. No.: 19/448,456

(22) Filed: Jan. 14, 2026

Related U.S. Application Data
(63) Continuation of application No. PCT/JP2024/034097, filed on Sep. 25, 2024.

(30) Foreign Application Priority Data
Sep. 26, 2023 (JP) 2023-163062

(51) Int. Cl. H03F 1/52; H03F 3/193; H03F 3/24; H03G 3/30

(52) U.S. Cl. CPC H03F 1/526; H03F 3/245; H03G 3/3042; H03F 3/193; H03F 2200/451; H03F 2203/21127; H03G 2201/208

(57) ABSTRACT

When the signal level of a signal outputted from a predetermined amplifier among the at least one amplifier is greater than or equal to a reference voltage, the comparator unit outputs, from its output terminal, an output signal which is in line with the difference between the signal level and the reference voltage. The DC blocking unit is electrically connected, at its first terminal, to the output terminal of the comparator unit, and outputs, from its second terminal, a signal obtained by blocking the DC component of the output signal. The detection unit is electrically connected, at its input terminal, to the second terminal of the DC blocking unit, and outputs, from its output terminal, a control signal, which is in line with the signal level of the signal outputted from the predetermined amplifier, to a predetermined circuit capable of reducing the gain of the power amplifier circuit.

### CROSS REFERENCE TO RELATED APPLICATION

This is a continuation of International Application No. PCT/JP2024/034097 filed on Sep. 25, 2024 which claims priority from Japanese Patent Application No. 2023-163062 filed on Sep. 26, 2023. The contents of these applications are incorporated herein by reference in their entireties.

### BACKGROUND OF THE DISCLOSURE

### Field of the Disclosure

The present disclosure relates to a protection circuit.

### Description of the Related Art

For example, a known power amplifier circuit having multiple power amplifiers includes a protection circuit which detects saturation of a power amplifier to protect the power amplifier (Japanese Unexamined Patent Application Publication No. 2008-294977).

### BRIEF SUMMARY OF THE DISCLOSURE

Japanese Unexamined Patent Application Publication No. 2008-294977 discloses a power amplifier circuit including a protection circuit which detects saturation of a power amplifier. The protection circuit described in Japanese Unexamined Patent Application Publication No. 2008-294977 has a detection terminal for detecting saturation of the power amplifier. The detection terminal is electrically connected to the output terminal of a subsequent-stage power amplifier. The protection circuit detects the collector voltage of the subsequent-stage power amplifier through the detection terminal. When the detected collector voltage of the subsequent-stage power amplifier is greater than or equal to a predetermined value, a current flows from the collector of the subsequent-stage power amplifier through the detection terminal into the protection circuit. When a current flows in from the subsequent-stage power amplifier through the detection terminal, the protection circuit draws a current from the base and the collector of a previous-stage power amplifier through a predetermined transistor. The predetermined value used in the protection circuit is a voltage value at which the subsequent-stage power amplifier operates in a safe operation range, and is a voltage value at which the subsequent-stage power amplifier may reliably obtain its desired amplification gain. That is, the protection circuit described in Japanese Unexamined Patent Application Publication No. 2008-294977 draws a current from the base and the collector of the previous-stage power amplifier in an overvoltage condition in which the collector voltage of the subsequent-stage power amplifier exceeds the rated voltage. Thus, the output from the previous-stage power amplifier is suppressed, achieving the prevention of a breakdown of the subsequent-stage power amplifier.

However, the protection circuit described in Japanese Unexamined Patent Application Publication No. 2008-294977 inputs a signal, which is outputted from the protection circuit, through a resistor to the predetermined transistor for suppressing the output from the previous-stage power amplifier. In this case, the DC component received by the predetermined transistor may cause delayed operations of the transistor, resulting in delayed suppression of the output from the previous-stage power amplifier.

Accordingly, it is a possible benefit of the present disclosure to provide a protection circuit which allows rapid execution of control of suppressing the gain of a power amplifier circuit.

A protection circuit according to an aspect of the present disclosure includes, in a power amplifier circuit including at least one amplifier, a comparator unit that, when the signal level of a signal outputted from a predetermined amplifier among the at least one amplifier is greater than or equal to a reference voltage, outputs, from an output terminal thereof, an output signal which is in line with the difference between the signal level and the reference voltage; a DC blocking unit that is electrically connected, at a first terminal thereof, to the output terminal of the comparator unit, and that outputs, from a second terminal thereof, a signal obtained by blocking the DC component of the output signal; and a detection unit that is electrically connected, at an input terminal thereof, to the second terminal of the DC blocking unit, and that outputs, from an output terminal thereof to a predetermined circuit capable of reducing the gain of the power amplifier circuit, a control signal which is in line with the signal level of the signal outputted from the predetermined amplifier.

The present disclosure may provide a protection circuit which allows rapid execution of control of suppressing the gain of a power amplifier circuit.

### BRIEF DESCRIPTION OF THE SEVERAL VIEWS OF THE DRAWINGS

FIG. 1 is a diagram illustrating a configuration example of a power amplifier circuit.

FIG. 2 is a diagram illustrating the configuration of a power amplifier circuit according to a first modified example.

FIG. 3 is a diagram illustrating the configuration of a power amplifier circuit according to a second modified example.

FIG. 4 is a diagram illustrating an overview of the configuration of a protection circuit.

FIG. 5 is a diagram illustrating a configuration example of a protection circuit.

FIG. 6 is a diagram illustrating the configuration of a protection circuit according to a first modified example.

FIG. 7 is a diagram illustrating another configuration example of the protection circuit of the first modified example.

FIG. 8 is a diagram illustrating the configuration of the protection circuit according to a second modified example.

FIG. 9 is a diagram illustrating another configuration example of the protection circuit according to the second modified example.

### DETAILED DESCRIPTION OF THE DISCLOSURE

Referring to the figures, embodiments of the present disclosure will be described below. Circuit elements designated with the same reference numerals are intended to be the same circuit elements, and repeated description will be avoided.

### Power Amplifier Circuit 1000

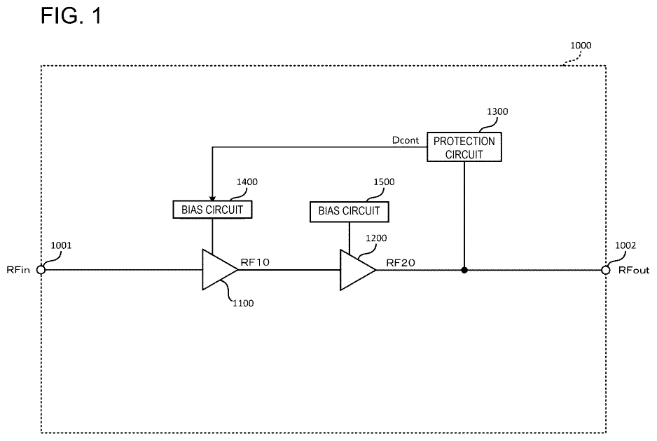

Referring to FIG. 1, the configuration of a power amplifier circuit according to a first embodiment will be described. FIG. 1 is a diagram illustrating a configuration example of a power amplifier circuit 1000.

The power amplifier circuit 1000, which is installed, for example, in a cellular phone, is used to amplify power of a signal that is to be transmitted to a base station. The power amplifier circuit 1000 is capable of amplifying power of a signal of a communication standard, such as 2G (second-generation mobile communication system), 3G (third-generation mobile communication system), 4G (fourth-generation mobile communication system), 5G (fifth-generation mobile communication system), LTE (Long Term Evolution)-FDD (Frequency Division Duplex), LTE-TDD (Time Division Duplex), LTE-Advanced, or LTE-Advanced Pro. The communication standard of a signal amplified by the power amplifier circuit 1000 is not limited to these.

As illustrated in FIG. 1, for example, the power amplifier circuit 1000 amplifies an input signal RFin, which is inputted from an input terminal 1001, and outputs an output signal RFout from an output terminal 1002. The input signal RFin is a radio-frequency (RF) signal, and has a frequency, for example, of about several GHz.

### Configuration

As illustrated in FIG. 1, the power amplifier circuit 1000 includes, for example, a driver-stage amplifier (hereinafter referred to as a “driver-stage amplifier 1100”) and a final-stage amplifier (hereinafter referred to as a “final-stage amplifier 1200”), and a protection circuit 1300.

The driver-stage amplifier 1100 is an amplifier, for example, which amplifies the input signal RFin to output a signal RF10. The driver-stage amplifier 1100 is biased, for example, by using a bias circuit 1400.

The final-stage amplifier 1200 is an amplifier connected in series to the driver-stage amplifier 1100. For example, the final-stage amplifier 1200 amplifies the signal RF10 to output a signal RF20. A signal based on the signal RF20 is outputted from the output terminal 1002 as the output signal RFout. The final-stage amplifier 1200 is biased, for example, by using a bias circuit 1500.

The protection circuit 1300 is a circuit which detects the signal level outputted from a predetermined amplifier among the amplifiers included in the power amplifier circuit 1000. Specifically, for example, the protection circuit 1300 is a circuit which detects the signal level of the signal RF20 outputted from the final-stage amplifier 1200. The signal level is, for example, a voltage. For example, the protection circuit 1300 decreases a bias supplied from the bias circuit 1400 to the driver-stage amplifier 1100 by using a signal (hereinafter referred to as a “control signal D_{cont}”) indicating the signal level. That is, as the control signal D_{cont} is larger, the gain of the driver-stage amplifier 1100 decreases.

Thus, for example, when the final-stage amplifier 1200 is saturated or starts to be saturated, the power amplifier circuit 1000 may decrease the gain of the driver-stage amplifier 1100 at an appropriate time to prevent a malfunction due to a voltage variation.

The protection circuit 1300 is not limited to the configuration in which the signal level of a signal outputted from the final-stage amplifier 1200 is detected, and may be configured, for example, to detect the signal level of a signal outputted from the driver-stage amplifier 1100. Description will be made below, for example, under the assumption that the protection circuit 1300 detects the signal level of a signal outputted from the final-stage amplifier 1200.

The protection circuit 1300 is not limited to the configuration in which a bias supplied from the bias circuit 1400 to the driver-stage amplifier 1100 is decreased. For example, when the power amplifier circuit 1000 includes an attenuator (not illustrated) which is disposed in series upstream of the driver-stage amplifier 1100, the protection circuit 1300 may output the control signal D_{cont} to the attenuator so that the attenuation rate of the attenuator is increased.

### FIRST MODIFIED EXAMPLE

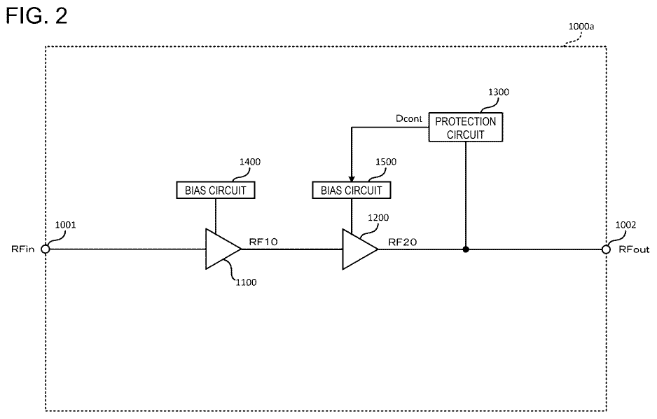

Referring to FIG. 2, the configuration of a power amplifier circuit 1000a according to a first modified example will be described. FIG. 2 is a diagram illustrating the configuration of the power amplifier circuit 1000a according to the first modified example. As illustrated in FIG. 2, in the power amplifier circuit 1000a according to the first modified example, the protection circuit 1300 uses the control signal D_{cont} to decrease a bias supplied from the bias circuit 1500 to the final-stage amplifier 1200. That is, as the control signal D_{cont} is larger, the gain of the final-stage amplifier 1200 decreases. Thus, when the final-stage amplifier 1200 is saturated or starts to be saturated, the power amplifier circuit 1000a may decrease a bias, which is provided to the final-stage amplifier 1200, at an appropriate time to avoid a breakdown of the final-stage amplifier 1200.

### SECOND MODIFIED EXAMPLE

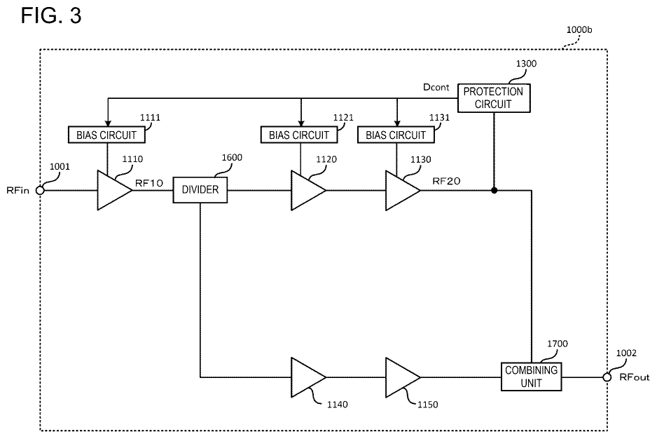

Referring to FIG. 3, the configuration of a power amplifier circuit 1000b according to a second modified example will be described. FIG. 3 is a diagram illustrating the configuration of the power amplifier circuit 1000b according to the second modified example. As illustrated in FIG. 3, compared with the power amplifier circuit 1000, the power amplifier circuit 1000b according to the second modified example includes a Doherty amplifier circuit. Specifically, for example, the power amplifier circuit 1000b includes a common driver-stage amplifier 1110, a driver-stage carrier amplifier 1120, a final-stage carrier amplifier 1130, a driver-stage peak amplifier 1140, a final-stage peak amplifier 1150, the protection circuit 1300, a divider 1600, and a combining unit 1700.

Typically, the Doherty amplifier circuit has a parallel connection of the driver-stage carrier amplifier 1120 and the final-stage carrier amplifier 1130, which operate regardless of the power level of an input signal, and the driver-stage peak amplifier 1140 and the final-stage peak amplifier 1150, which turn OFF when the power level of the input signal is low and which turn ON when the power level is high. The Doherty amplifier circuit causes the peak amplifiers to operate at a time when the carrier amplifiers approach saturation. Thus, the Doherty amplifier circuit achieves improvement of efficiency compared with a commonly-used power amplifier circuit.

The carrier amplifiers are biased, for example, in Class A, Class AB, or Class B. The peak amplifiers are biased, for example, in Class A, Class AB, Class B, or Class C.

For example, the divider 1600 divides the signal RFin to a signal, which is to be inputted to the carrier amplifiers, and a signal, which is to be inputted to the peak amplifiers. For example, the divider 1600 may be a distributed parameter circuit such as a 3-dB coupled-line coupler or a Wilkinson power divider. For example, the combining unit 1700 combines the signal RF20, which is outputted from the carrier amplifiers and passes through a phase shifter (not illustrated), with a signal, which is outputted from the peak amplifiers, to output a signal RFout.

In the power amplifier circuit 1000b, the protection circuit 1300 properly detects the saturation state of the final-stage carrier amplifier 1130, and thus decreases at least any of the biases from bias circuits 1111, 1121, and 1131 of the common driver-stage amplifier 1110, the driver-stage carrier amplifier 1120, and the final-stage carrier amplifier 1130. That is, the protection circuit 1300 decreases at least any of the biases from the bias circuits 1111, 1121, and 1131 of the common driver-stage amplifier 1110, the driver-stage carrier amplifier 1120, and the final-stage carrier amplifier 1130 by using the control signal D_{cont} in line with the signal level of the signal RF20 outputted from the final-stage carrier amplifier 1130. Thus, when the final-stage carrier amplifier 1130 is saturated or starts to be saturated, the power amplifier circuit 1000b may decrease the bias, which is provided to the final-stage carrier amplifier 1130, at an appropriate time to prevent a breakdown of the final-stage carrier amplifier 1130.

Thus, the power amplifier circuit 1000b adjusts the bias to a carrier amplifier of the Doherty amplifier circuit to prevent a breakdown of the final-stage carrier amplifier 1130. Specifically, to achieve a high-efficient operation, the Doherty amplifier circuit makes the voltage amplitude of the power supply voltage, which is supplied to the carrier amplifiers, larger than that of the power supply voltage supplied to the peak amplifiers. Thus, in the Doherty amplifier circuit, an instantaneous upper-peak voltage at a carrier amplifier's output terminal (the collector or drain of a transistor included in the carrier amplifier) is higher than that at a peak amplifier's output terminal (the collector or drain of a transistor included in the peak amplifier). This leads to a high probability of a breakdown of the carrier amplifiers. Therefore, the power amplifier circuit 1000b has a configuration in which the protection circuit 1300 protects the carrier amplifiers which are more likely to be broken down.

### Protection Circuit 1300

The configuration of the protection circuit 1300 will be described specifically. Description will be made below, for example, under the assumption that a bipolar transistor is employed as a transistor. The transistor may be a FET (Field Effect Transistor). That is, a FET may be employed by reading the emitter, the collector, and the base of a bipolar transistor as the source, the drain, and the gate, respectively, of a FET.

### Overview of Protection Circuit 1300

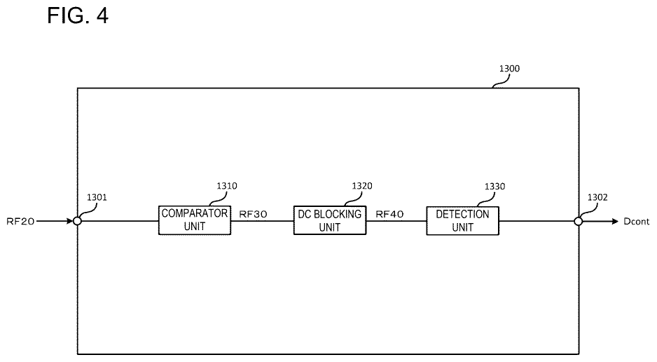

Referring to FIG. 4, an overview of the configuration of the protection circuit 1300 will be described. FIG. 4 is a diagram illustrating an overview of the configuration of the protection circuit 1300. As illustrated in FIG. 4, the protection circuit 1300 includes, for example, an input terminal 1301, a detection terminal 1302, a comparator unit 1310, a DC blocking unit 1320, and a detection unit 1330.

For example, the input terminal 1301 is a terminal electrically connected to the output terminal of the final-stage amplifier 1200.

The detection terminal 1302 is a terminal for detecting the signal level of the output of the final-stage amplifier 1200. For example, the detection terminal 1302 is electrically connected to the bias circuit 1400 of the driver-stage amplifier 1100.

The comparator unit 1310 receives, at its input terminal, the output signal RF20 outputted from the output terminal of the final-stage amplifier 1200. When the signal level of the output signal RF20 is greater than or equal to a reference voltage, the comparator unit 1310 outputs, from its output terminal, an output signal RF30 in line with the difference between the signal level of the output signal RF20 and the reference voltage. The comparator unit 1310 is electrically connected, at its output terminal, to the DC blocking unit 1320 which is described below.

The DC blocking unit 1320 blocks the DC component of the output signal RF30, which is outputted from the comparator unit 1310, to output an output signal RF40. That is, the DC blocking unit 1320 passes the high-frequency component of the output signal RF30. For example, the DC blocking unit 1320 is electrically connected, at its first terminal, to an output terminal of the comparator unit 1310, and is electrically connected, at its second terminal, to the detection unit 1330.

The detection unit 1330 detects the output signal RF40 from which the DC component has been blocked by the DC blocking unit 1320. The detection unit 1330 converts the output signal into the DC component to output the control signal D_{cont}.

For example, the detection unit 1330 is electrically connected, at its input terminal, to the second terminal of the DC blocking unit 1320, and is electrically connected, at its output terminal, to the detection terminal 1302.

Thus, when an instantaneous upper-peak voltage of the output signal outputted from the final-stage amplifier 1200 is close to a voltage causing a breakdown of the amplifier, the protection circuit 1300 outputs, from the comparator unit 1310, the output signal RF30 which vibrates in the period of the output signal RF20 outputted from the final-stage amplifier 1200. The protection circuit 1300 blocks the DC component of the output signal RF30, which is outputted from the comparator unit 1310, to mitigate a delay, which is caused by the DC component, of the response time of the comparator unit 1310. This also achieves suppression of variation of the bias point of the detection unit 1330.

In contrast, the protection circuit described in Japanese Unexamined Patent Application Publication No. 2008-294977 needs much time to stabilize the DC component of a signal inputted to the predetermined transistor for suppressing the output of the previous-stage power amplifier. In other words, in the protection circuit described in Japanese Unexamined Patent Application Publication No. 2008-294977, the DC component inputted to the transistor acts on the operation of the protection circuit itself, needing much time until the response is stabilized.

That is, the protection circuit 1300 is configured to block the DC component of an output signal of the comparator unit 1310, causing the output signal not to act on the operation of the protection circuit 1300. Thus, compared with the related art, the protection circuit 1300 has a remarkable effect to mitigate a delay of the response time of the component.

The protection circuit 1300 may include an amplification unit 1340. The amplification unit 1340 is connected in series between the comparator unit 1310 and the DC blocking unit 1320. Thus, the configuration of the protection circuit 1300, in which a radio frequency signal is outputted from the comparator unit 1310, enables amplification with a simple configuration. The protection circuit 1300 amplifies the output signal RF30 outputted from the comparator unit 1310, making the control signal D_{cont} larger. This achieves sensitive monitoring of the saturation state of the final-stage amplifier 1200. Description will be made below, for example, under the assumption that the protection circuit 1300 includes the amplification unit 1340.

### Configuration of Protection Circuit 1300

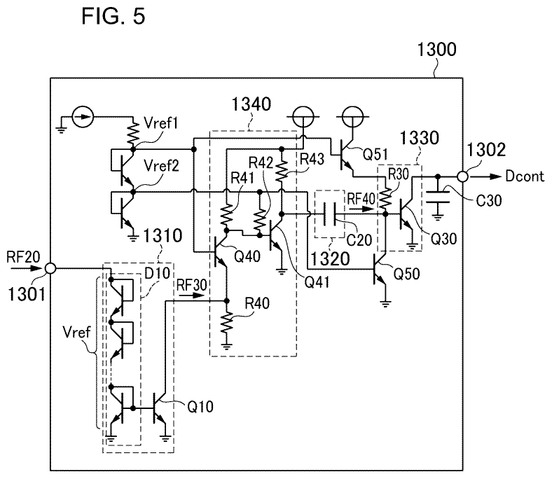

Referring to FIG. 5, a specific configuration example of the protection circuit 1300 will be described. FIG. 5 is a diagram illustrating a configuration example of the protection circuit 1300. As illustrated in FIG. 5, the protection circuit 1300 includes the comparator unit 1310, the amplification unit 1340, the DC blocking unit 1320, and the detection unit 1330.

For example, the comparator unit 1310 includes a reference-potential unit D10 and a transistor Q10.

For example, the reference-potential unit D10 is formed of multiple diodes connected in series to one another. The reference-potential unit D10 is electrically connected, at its anode which is a first end, to the input terminal 1301, and is electrically connected, at its cathode which is a second end, to the ground. As illustrated in FIG. 5, the diodes may be diode-connected transistors. For example, the reference-potential unit D10 may be formed of ten diode-connected transistors, which are connected in series to one another, to generate a reference voltage V_{ref}.

The transistor Q10 is connected, in a current mirror configuration, to any of the diode-connected transistors (for example, a transistor positioned at the second end) included in the reference-potential unit D10. For example, the transistor Q10 is electrically connected, at its emitter, to the ground; is electrically connected, at its base, to the base of one of the diode-connected transistors included in the reference-potential unit D10; and is electrically connected, at its collector, to the emitter of a transistor Q40 of the amplification unit 1340. Thus, the comparator unit 1310 may detect saturation of the final-stage amplifier 1200 by using a simple configuration.

For example, the amplification unit 1340 includes at least one transistor. Description will be made, for example, under the assumption that the amplification unit 1340 includes the transistor Q40 and a transistor Q41.

The transistor Q40 is supplied, at its base, with a reference voltage V_{ref1}; is electrically connected, at its emitter, to the collector of the transistor Q10 of the comparator unit 1310 to receive the output signal RF30; and is electrically connected, at its collector, to the base of the transistor Q41. That is, the emitter of the transistor Q40 corresponds to the amplification unit 1340's input terminal electrically connected to the output terminal of the comparator unit 1310. The emitter of the transistor Q40 is electrically connected to the ground through a resistor R40. The collector of the transistor Q40 is electrically connected to a power supply through a resistor R41.

The transistor Q41 is supplied, at its base, with a reference voltage V_{ref2} through a resistor R42; is electrically connected, at its emitter, to the ground; and is electrically connected, at its collector, to the first end of the DC blocking unit 1320. That is, the collector of the transistor Q41 corresponds to the amplification unit 1340's output terminal electrically connected to the first terminal of the DC blocking unit 1320. The collector of the transistor Q41 is electrically connected to the power supply through a resistor R43. The base of the transistor Q41 may be electrically connected to the collector of the transistor Q40 through a capacitor (not illustrated) for blocking the DC component. Thus, the DC component of the signal RF20 may be blocked more reliably, achieving more reliable elimination of the response delay.

For example, the DC blocking unit 1320 includes a capacitor C20. The capacitor C20 is electrically connected, at its first terminal, to the collector of the transistor Q41; and is electrically connected, at its second terminal, to the detection unit 1330.

The DC blocking unit 1320 blocks the DC component, which is included in the output signal RF20 having been amplified by the amplification unit 1340 and which causes the stabilization to take time due to influence of the operation of the comparator unit 1310 (for example, the operation of the transistor Q10). That is, the DC blocking unit 1320 outputs, to the detection unit 1330, the output signal RF40 which is the high-frequency component. Thus, the DC blocking unit 1320 separates the comparator unit 1310 from the detection unit 1330 in a DC viewpoint so that the DC component, which causes the stabilization to take time, does not act on the detection unit 1330. In other words, the protection circuit 1300 blocks the DC component which causes the stabilization to take time, and uses the high-frequency component as a detection signal. This achieves the elimination of the response delay which occurs when the DC component outputted from the comparator unit 1310 is used as a detection signal.

For example, the detection unit 1330 includes a transistor Q30. The transistor Q30 is connected, at its base, in series to the second end of the DC blocking unit 1320 to receive the output signal RF40; is electrically connected, at its emitter, to the ground; and is electrically connected, at its collector (output terminal), to the detection terminal 1302. Desirably, a capacitor C30, which serves as a filter for suppression of the fundamental wave, is disposed between the collector of the transistor Q30 and the ground. The base of the transistor Q30 is supplied with the reference voltage V_{ref1} through a transistor Q51 and a resistor R30. By using a capacitor (not illustrated) for smoothing a radio frequency signal, the transistor Q30 smooths the high-frequency component of the output signal RF40, which is outputted from the DC blocking unit 1320, to output a direct current.

In the description above, the transistor Q30 is electrically connected, at its collector, to the detection terminal 1302. However, the transistor Q30 may be electrically connected, at its emitter, to the detection terminal 1302. This makes the input impedance of the detection unit 1330 high, making the input current small. That is, the AC interaction between the detection unit 1330 and the comparator unit 1310 may be suppressed, achieving stabilization of the AC output from the comparator unit 1310.

### Operation of Protection Circuit 1300

The operation of the protection circuit 1300 will be described.

An instantaneous upper-peak voltage at the collector or drain of the final-stage amplifier 1200 is larger as the final-stage amplifier 1200 gets closer to saturation. In the comparator unit 1310, when the voltage at the collector or drain of the final-stage amplifier 1200 is greater than or equal to the reference voltage V_{ref} generated by the diode-connected transistors, the diode-connected transistors (reference-potential unit D10) turn ON. That is, the comparator unit 1310 is in the conductive state for the period in which the voltage (signal level) of the input signal RF10 inputted to the input terminal 1301 is greater than or equal to the reference voltage V_{ref}.

The range of angles representing a period of the conductive state is referred to as the conduction angle. As the input signal RF10 is larger, the conduction angle increases. As the conduction angle increases, the DC component of the output signal RF30 outputted from the comparator unit 1310 increases.

In the conductive state, the transistor Q10, which is connected in a current mirror configuration, is supplied, at its base, with a voltage, causing the transistor Q10 to turn ON. When the transistor Q10 turns ON, a current flows through the collector of the transistor Q10. Thus, the transistor Q40 of the amplification unit 1340 turns ON, and a current flows through the collector of the transistor Q40. A current flows through the base of the transistor Q41, causing the transistor Q41 to operate. The DC blocking unit 1320 outputs, to the detection unit 1330, the output signal RF40, which is the high-frequency component and from which the DC component of the signal outputted from the collector of the transistor Q41 has been blocked. The detection unit 1330 amplifies the output signal RF40, from which the DC component has been blocked, and smooths the amplified signal for output as the control signal D_{cont}.

### Protection Circuit 1300a According to First Modified Example

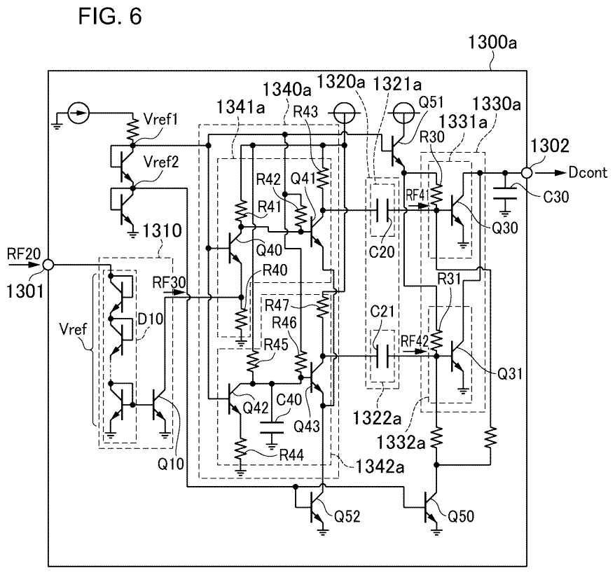

Referring to FIG. 6, a protection circuit 1300a according to a first modified example will be described. FIG. 6 is a diagram illustrating the configuration of the protection circuit 1300a according to the first modified example. In the description below, only configurations different from those of the protection circuit 1300 will be described, and components which are not particularly described are substantially the same as those of the protection circuit 1300. Compared with the protection circuit 1300, the protection circuit 1300a has a configuration in which the amplification unit 1340, the DC blocking unit 1320, and the detection unit 1330 are formed as differential circuits.

As illustrated in FIG. 6, the protection circuit 1300a includes an amplification unit 1340a, a DC blocking unit 1320a, and a detection unit 1330a.

The amplification unit 1340a is formed of a differential circuit of a first amplification unit 1341a and a second amplification unit 1342a. That is, the amplification unit 1340a amplifies the output signal RF30 outputted from the comparator unit 1310, and converts the output signal RF30 to a differential signal.

For example, the first amplification unit 1341a may have a configuration in which the transistors Q40 and Q41 are cascade-connected (that is, the output terminal of a previous-stage transistor among multiple transistors is connected to the input terminal of a subsequent-stage transistor).

The transistor Q40 is supplied, at its base, with a reference voltage V_{ref1}; is electrically connected, at its emitter, to the ground through the resistor R40; and is electrically connected, at its collector, to the base of the transistor Q41. The transistor Q40 receives, at its emitter, the output signal RF30 outputted from the comparator unit 1310. The transistor Q41 is supplied, at its base, with the reference voltage V_{ref1} through the resistor R42; is electrically connected, at its emitter, to the ground through a transistor Q52 (for example, a transistor which serves as a current source); and is electrically connected, at its collector, to a first DC blocking unit 1321a described below.

For example, the second amplification unit 1342a may have a configuration in which multiple transistors Q42 and Q43 are cascade-connected.

The transistor Q42 is supplied, at its base, with the reference voltage V_{ref1}; is electrically connected, at its emitter, to the ground through a resistor R44; and is electrically connected, at its collector, to the base of the transistor Q43. The collector of the transistor Q42 is connected to the ground through a capacitor C40 for attenuating the high-frequency component. The transistor Q43 is supplied, at its base, with the reference voltage V_{ref1} through a resistor R46; is electrically connected, at its emitter, to the ground through the transistor Q52; and is electrically connected, at its collector, to a second DC blocking unit 1322a described below.

The DC blocking unit 1320a includes the first DC blocking unit 1321a and the second DC blocking unit 1322a. The first DC blocking unit 1321a is a capacitor which is electrically connected, at its first terminal, to the collector of the transistor Q41 of the first amplification unit 1341a and which is electrically connected, at its second terminal, to a first detection unit 1331a described below. The first DC blocking unit 1321a outputs, from its second terminal, an output signal RF41 from which the DC component of the output signal RF30 has been blocked. The second DC blocking unit 1322a is a capacitor which is connected, at its first terminal, in series to the collector of the transistor Q43 of the second amplification unit 1342a and which is connected, at its second terminal, in series to a second detection unit 1332a described below. The second DC blocking unit 1322a outputs, from its second terminal, an output signal RF42 having a phase different from that of the output signal RF40 by about 180 degrees. “About 180 degrees” includes, for example, a range from 135 degrees to 225 degrees.

For example, the detection unit 1330a includes the transistor Q30 and a transistor Q31. The transistor Q30 is electrically connected, at its base, to the second terminal of the first DC blocking unit 1321a; is electrically connected, at its emitter, to the ground; and is electrically connected, at its collector, to the detection terminal 1302. The transistor Q31 is electrically connected, at its base, to the second terminal of the second DC blocking unit 1322a; is electrically connected, at its emitter, to the ground; and is electrically connected, at its collector, to the detection terminal 1302. That is, the detection unit 1330a outputs, from the detection terminal 1302, a signal which is obtained by combining a signal outputted from the collector of the transistor Q30 with a signal which is outputted from the collector of the transistor Q31 and which has a phase different by about 180 degrees from that of the signal outputted from the collector of the transistor Q30. The bases of the transistors Q30 and Q31 are electrically connected to the ground through a transistor Q50 (for example, a transistor which serves as a current source).

Thus, the protection circuit 1300a is formed of the differential circuits. This causes leaking odd-order harmonic components to cancel each other out, achieving the suppression of the influence from the leakage on the circuit. Thus, the protection circuit 1300a achieves a reduction of the size of a filter circuit (not illustrated) which extracts the DC component and which is disposed downstream, resulting in further mitigation of the delay of response time.

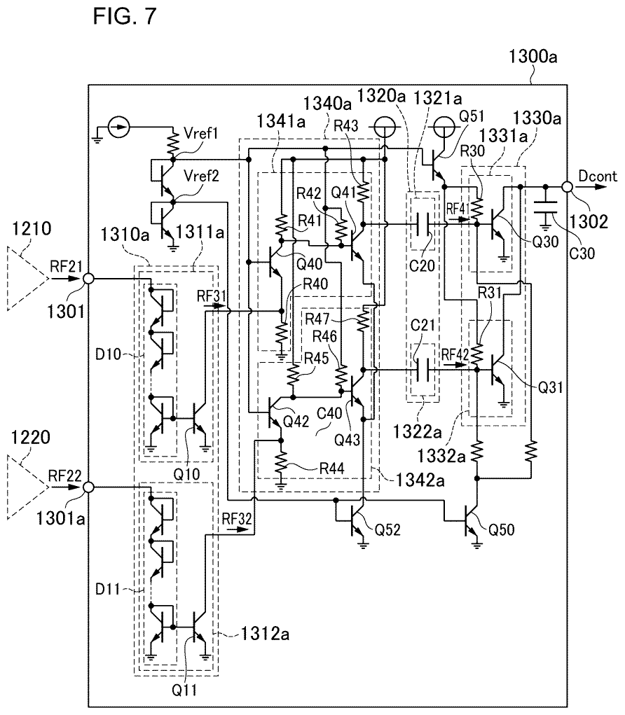

Referring to FIG. 7, the configuration of the protection circuit 1300a in the case where a differential signal is inputted from a differential final-stage amplifier 1200 to the protection circuit 1300a will be described. FIG. 7 is a diagram illustrating another configuration example of the protection circuit 1300a according to the first modified example.

As illustrated in FIG. 7, the protection circuit 1300a is configured to receive, from the differential final-stage amplifier 1200, differential signals RF21 and RF22 which have phases different by about 180 degrees from each other. Specifically, the protection circuit 1300a includes a comparator unit 1311a and a comparator unit 1312a. Description will be made under the assumption that the final-stage amplifier 1200 includes a first final-stage amplifier 1210 and a second final-stage amplifier 1220.

The comparator unit 1311a includes the reference-potential unit D10 and the transistor Q10. The reference-potential unit D10 and the transistor Q10 are the same as those of the comparator unit 1310, and will not be described.

The comparator unit 1312a includes a reference-potential unit D11 and a transistor Q11.

For example, the reference-potential unit D11 has a configuration in which multiple diodes are connected in series to one another. The reference-potential unit D11 is electrically connected, at its anode which is a first end, to an input terminal 1301a; and is electrically connected, at its cathode which is a second end, to the ground. As illustrated in FIG. 7, for example, the diodes may be diode-connected transistors. For example, the reference-potential unit D11 may be formed of ten diode-connected transistors, which are connected in series to one another, to generate the reference voltage V_{ref}.

The transistor Q11 is connected, in a current mirror configuration, to any of the diode-connected transistors (for example, a transistor positioned at the second end) included in the reference-potential unit D11. For example, the transistor Q11 is electrically connected, at its emitter, to the ground; is electrically connected, at its base, to the base of one of the diode-connected transistors included in the reference-potential unit D11; and is electrically connected, at its collector, to the emitter of the transistor Q42 of the second amplification unit 1342a.

Thus, the protection circuit 1300a illustrated in FIG. 7 is formed of differential circuits. This causes leaking odd-order harmonic components to cancel each other out, achieving the suppression of the influence from the leakage on the circuit. In addition, the protection circuit 1300a may be compatible with the differential final-stage amplifier 1200.

### Protection Circuit 1300b According to Second Modified Example

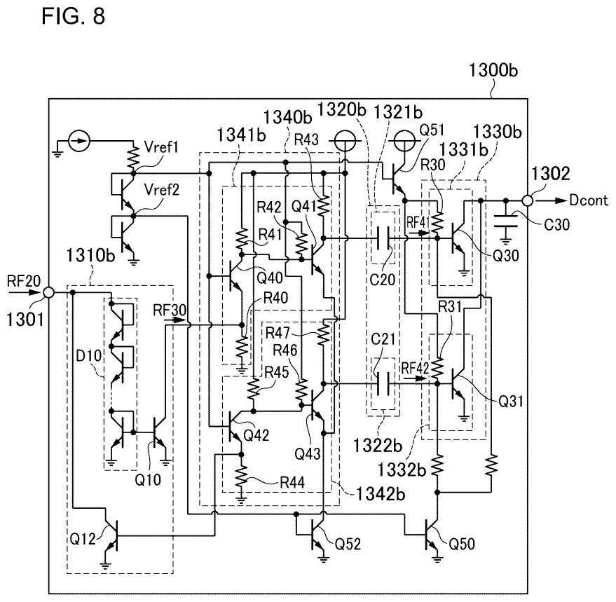

Referring to FIG. 8, a protection circuit 1300b according to a second modified example will be described. FIG. 8 is a diagram illustrating the configuration of the protection circuit 1300b according to the second modified example. In the description below, only components different from those of the protection circuit 1300a in FIG. 6 will be described, and components which are not described particularly are substantially the same as those of the protection circuit 1300a in FIG. 6. For example, an amplification unit 1340b, a DC blocking unit 1320b, and a detection unit 1330b in the protection circuit 1300b are substantially the same as the amplification unit 1340a, the DC blocking unit 1320a, and the detection unit 1330a in the protection circuit 1300a, and will not be described. Compared with the protection circuit 1300a, the protection circuit 1300b has a configuration in which a transistor Q12 is added to the comparator unit 1310 of the protection circuit 1300a.

Specifically, as illustrated in FIG. 8, a comparator unit 1310b of the protection circuit 1300b includes the transistor Q12. The transistor Q12 receives, at its collector, the input signal RF20 outputted from the final-stage amplifier 1200; is electrically connected, at its base, to the emitter of the transistor Q42 of the second amplification unit 1342b; and is electrically connected, at its emitter, to the ground. The transistor Q12 operates in the state in which an instantaneous lower-peak voltage at the collector of the final-stage amplifier 1200 approaches to 0 V. In the state in which the final-stage amplifier 1200 is close to saturation, an instantaneous lower-peak voltage at the collector of the final-stage amplifier 1200 approaches 0 V. That is, the protection circuit 1300b outputs the control signal D_{cont} from the detection unit 1330b even in the saturation state of the final-stage amplifier 1200 in which an instantaneous lower-peak voltage of the final-stage amplifier 1200 approaches 0 V.

In the protection circuit 1300b, when an instantaneous upper-peak voltage at the collector of the final-stage amplifier 1200 is greater than or equal to the reference voltage V_{ref}, the reference-potential unit D10 and the transistor Q10 operate. When an instantaneous lower-peak voltage at the collector of the final-stage amplifier 1200 approaches 0 V, the transistor Q12 operates. That is, the protection circuit 1300b detects the saturation state of the final-stage amplifier 1200 on the basis of the upper limit and the lower limit of the collector voltage of the final-stage amplifier 1200, achieving the suppression of the output of the final-stage amplifier 1200. More specifically, when an instantaneous upper-peak voltage at the collector of the final-stage amplifier 1200 is greater than or equal to the reference voltage V_{ref} and an instantaneous lower-peak voltage at the collector of the final-stage amplifier 1200 approaches 0 V, compared with the protection circuit 1300a, the protection circuit 1300b may output the control signal D_{cont} at a higher rate, achieving more reliable prevention of a breakdown of the final-stage amplifier 1200.

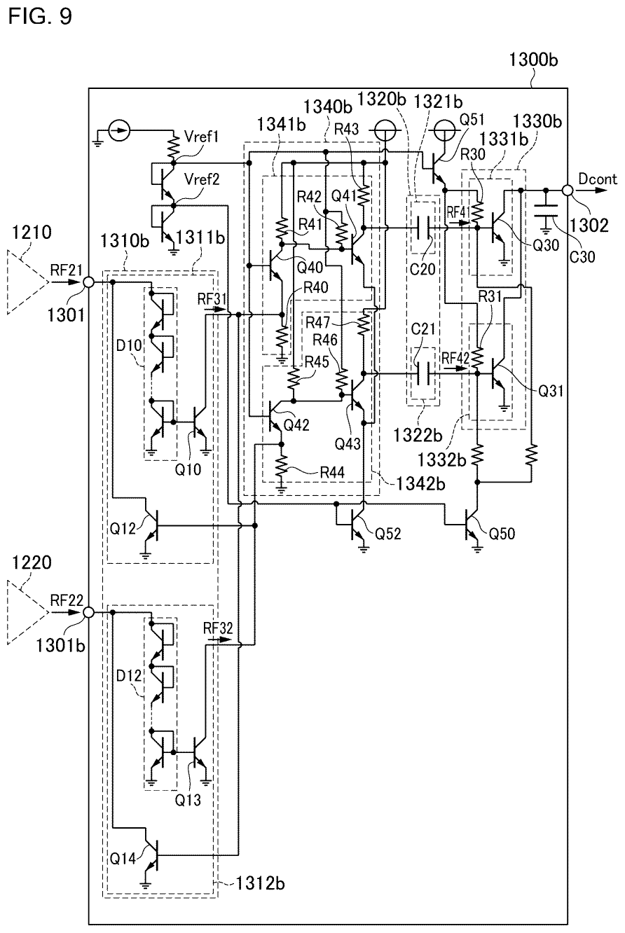

Referring to FIG. 9, the configuration of the protection circuit 1300b in the case where the protection circuit 1300b receives a differential signal from the differential final-stage amplifier 1200 will be described. FIG. 9 is a diagram illustrating another configuration example of the protection circuit 1300b according to the second modified example.

As illustrated in FIG. 9, the protection circuit 1300b is configured to receive, from the differential final-stage amplifier 1200, differential signals RF21 and RF22 having phases different by about 180 degrees from each other. Specifically, the protection circuit 1300b includes a comparator unit 1311b and a comparator unit 1312b. Description will be made under the assumption that the final-stage amplifier 1200 includes the first final-stage amplifier 1210 and the second final-stage amplifier 1220.

The comparator unit 1311b includes the reference-potential unit D10, the transistor Q10, and the transistor Q12. The comparator unit 1311b receives, at its input terminal 1301, the differential signal RF21 from the first final-stage amplifier 1210. The reference-potential unit D10, the transistor Q10, and the transistor Q12 of the comparator unit 1311b are the same as the reference-potential unit D10, the transistor Q10, and the transistor Q12 of the comparator unit 1310b illustrated in FIG. 8, and will not be described.

The comparator unit 1312b includes a reference-potential unit D12, a transistor Q13, and a transistor Q14. The comparator unit 1312b receives, at its input terminal 1301b from the second final-stage amplifier 1220, the differential signal RF22 having a phase different by about 180 degrees from that of the differential signal RF21.

For example, the reference-potential unit D12 is formed of multiple diodes connected in series to one another. The reference-potential unit D12 is electrically connected, at its anode which is a first end, to the input terminal 1301b; and is electrically connected, at its cathode which is a second end, to the ground. The diodes may be, for example, diode-connected transistors. For example, the reference-potential unit D12 may be formed of ten diode-connected transistors, which are connected in series to one another, to generate the reference voltage V_{ref}.

The transistor Q13 is connected, in a current mirror configuration, to any of the diode-connected transistors (for example, a transistor positioned at the second end) included in the reference-potential unit D12. For example, the transistor Q13 is electrically connected, at its emitter, to the ground; is electrically connected, at its base, to the base of one of the diode-connected transistors included in the reference-potential unit D12; and is electrically connected, at its collector, to the emitter of the transistor Q42 of the amplification unit 1342b.

The transistor Q14 receives, at its collector, the differential signal RF22 outputted from the second final-stage amplifier 1220; is electrically connected, at its base, to the emitter of the transistor Q40 of the amplification unit 1341b; and is electrically connected, at its emitter, to the ground. The transistor Q14 operates in the state in which an instantaneous lower-peak voltage at the collector of the second final-stage amplifier 1220 approaches 0 V. In the state in which the second final-stage amplifier 1220 is close to saturation, an instantaneous lower-peak voltage at the collector of the second final-stage amplifier 1220 approaches 0 V. That is, the protection circuit 1300b outputs the control signal D_{cont} from the detection unit 1330b even in the saturation state of the second final-stage amplifier 1220 in which an instantaneous lower-peak voltage of the second final-stage amplifier 1220 approaches 0 V.

In the protection circuit 1300b illustrated in FIG. 9, when an instantaneous upper-peak voltage at the collector of the differential final-stage amplifier 1200 (1210, 1220) is greater than or equal to the reference voltage V_{ref}, the reference-potential unit D10 and the transistor Q10 of the comparator unit 1311b and the reference-potential unit D12 and the transistor Q13 of the comparator unit 1312b operate. Further, in the protection circuit 1300b illustrated in FIG. 9, when an instantaneous lower-peak voltage at the collector of the final-stage amplifier 1200 approaches 0 V, the transistor Q12 of the comparator unit 1311b and the transistor Q14 of the comparator unit 1312b operate. That is, the protection circuit 1300b detects the saturation state of the differential final-stage amplifier 1200 on the basis of the upper limit and the lower limit of the collector voltage of the differential final-stage amplifier 1200, achieving the suppression of the output of the differential final-stage amplifier 1200. More specifically, when an instantaneous upper-peak voltage at the collector of the differential final-stage amplifier 1200 is greater than or equal to the reference voltage V_{ref} and an instantaneous lower-peak voltage at the collector of the differential final-stage amplifier 1200 approaches 0 V, compared with the protection circuit 1300a and the differential protection circuit in FIG. 8, the protection circuit 1300b illustrated in FIG. 9 may output the control signal D_{cont} at a higher rate, achieving more reliable prevention of a breakdown of the differential final-stage amplifier 1200.

### Conclusion

<1> In the power amplifier circuit 1000 including at least one amplifier, the protection circuit 1300 includes the comparator unit 1310, the DC blocking unit 1320, and the detection unit 1330. When the signal level of the signal RF20 (for example, when the final-stage amplifier 1200 is differential, the signal RF21 and the signal RF22) outputted, for example, from the final-stage amplifier 1200 (predetermined amplifier) among the at least one amplifier is greater than or equal to a reference voltage, the comparator unit 1310 outputs, from its output terminal, the output signal RF30 which is in line with the difference between the signal level and the reference voltage V_{ref}. The DC blocking unit 1320, which is electrically connected, at its first terminal, to the output terminal of the comparator unit 1310, outputs, from its second terminal, a signal obtained by blocking the DC component of the output signal RF30. The detection unit 1330, which is electrically connected, at its base (input terminal), to the second terminal of the DC blocking unit 1320, outputs, from its collector (output terminal) to a predetermined circuit which is capable of reducing the gain of the power amplifier circuit 1000, the control signal D_{cont} which is in line with the signal level of the signal outputted from the final-stage amplifier 1200 (predetermined amplifier). Thus, the protection circuit 1300 blocks the DC component of the output signal RF30 outputted from the comparator unit 1310, achieving the mitigation of the delay, which is caused by the DC component, of the response time of the comparator unit 1310. In addition, variation of the bias point of the detection unit 1330 may be suppressed. Therefore, when the final-stage amplifier 1200 is saturated or starts to be saturated, the protection circuit 1300 decreases the gain of the driver-stage amplifier 1100 or the final-stage amplifier 1200 at an appropriate time, achieving the suppression of the gain of the entire circuit. This enables the protection circuit 1300 to avoid a breakdown of the final-stage amplifier 1200 which is caused by a voltage variation of the power amplifier circuit 1000.
<2> The protection circuit 1300 according to <1> further includes the amplification unit 1340 which is electrically connected, at its input terminal (for example, the emitter of the transistor Q40), to the output terminal of the comparator unit 1310 and which is electrically connected, at its output terminal (for example, the collector of the transistor Q41), to the first terminal of the DC blocking unit 1320. This achieves the protection circuit 1300's sensitive monitoring of the saturation state of the final-stage amplifier 1200.
<3> In the protection circuit according to <2>, the amplification unit 1340a of the protection circuit 1300a includes the differential circuit (the circuit including the transistors Q40 to Q43) that includes the transistor Q40 (first transistor), which receives, at its emitter, the output signal RF30, and the transistor Q42 (second transistor), which is electrically connected, at its emitter or source, to a reference potential. The DC blocking unit 1320a includes the capacitor C20 (first capacitor) which is electrically connected, at its first terminal, to the collector (or drain) of the transistor Q41 (first transistor) connected, at its base, to the collector (or drain) of the transistor Q40, and a capacitor C21 (second capacitor), which is electrically connected, at its first terminal, to the collector of the transistor Q43 (second transistor) connected, at its base, to the collector (or drain) of the transistor Q42. The detection unit 1330a includes the transistor Q30 (third transistor), which is electrically connected, at its base, to the second terminal of the capacitor C20 (first capacitor), and the transistor Q31 (fourth transistor), which is electrically connected, at its base, to the second terminal of the capacitor C21 (second capacitor). Thus, the protection circuit 1300a, which is formed of differential circuits, causes leaking odd-order harmonic components to cancel each other out, achieving the suppression of the influence from the leakage on the circuit. Thus, the protection circuit 1300a achieves a reduction of the size of a filter circuit (not illustrated), which extracts the DC component and which is disposed downstream, and further mitigation of the delay of response time.
<4> In the protection circuit according to any one of <1> to <3>, the comparator unit 1310 of the protection circuit 1300 includes multiple diodes or multiple diode-connected transistors which are electrically connected, at their first end, to the input terminal 1301 receiving the signal RF20 outputted from the final-stage amplifier 1200 (predetermined amplifier) and which are electrically connected, at their second end, to the ground (reference potential). The comparator unit 1310 includes the transistor Q10 (fifth transistor) which is connected, in a current mirror configuration, to any of the diodes or the diode-connected transistors and which is electrically connected, at its collector, to the first terminal of the DC blocking unit 1320. Thus, the protection circuit 1300 may detect saturation of the final-stage amplifier 1200 by using a simple configuration.
<5> In the protection circuit according to any one of <1> to <3>, the comparator unit 1310 includes multiple diodes or multiple diode-connected transistors which are electrically connected, at their first end, to the input terminal 1301 receiving the signal RF20 outputted from the final-stage amplifier 1200 (predetermined amplifier) and which are electrically connected, at their second end, to the ground (reference potential). The comparator unit 1310 further includes the transistor Q10 (fifth transistor) which is connected, in a current mirror configuration, to any of the diodes or any of the diode-connected transistors. The protection circuit 1300 further includes the amplification unit 1340 which includes the transistor Q40 (sixth transistor) electrically connected, at its emitter or source, to the collector or drain of the transistor Q10 (fifth transistor). The DC blocking unit 1320 is electrically connected, at its first terminal, to the collector or drain of the transistor Q40 (sixth transistor). The detection unit 1330 includes the transistor Q30 (seventh transistor) electrically connected, at its base or gate, to the second terminal of the DC blocking unit 1320. Thus, the protection circuit 1300 may detect saturation of the final-stage amplifier 1200 by using a simple configuration.
<6> In the protection circuit according to any one of <1> to <5>, the comparator unit 1310b of the protection circuit 1300b includes the transistor Q12 (eighth transistor) which receives, at its collector, the signal RF20 outputted from the final-stage amplifier 1200 (predetermined amplifier) and which is electrically connected, at its base, to the emitter of the transistor Q42 (second transistor). Thus, when an instantaneous upper-peak voltage at the collector of the final-stage amplifier 1200 is greater than or equal to the reference voltage V_{ref} and an instantaneous lower-peak voltage at the collector of the final-stage amplifier 1200 approaches 0 V, compared with the protection circuit 1300a, the protection circuit 1300b may output the control signal D_{cont} at a higher rate, achieving more reliable suppression of the gain of the power amplifier circuit 1000.
<7> In the protection circuit according to any one of <3> to <6>, the final-stage amplifier 1200 (predetermined amplifier) of the power amplifier circuit 1000 (amplifier circuit) is the first final-stage amplifier 1210 (first amplifier) and the second final-stage amplifier 1220 (second amplifier) which form a differential circuit. The comparator unit 1310a of the protection circuit 1300a includes the comparator unit 1311a (first comparator unit) and the comparator unit 1312a (second comparator unit). When the signal level of the signal RF21 outputted from the first final-stage amplifier 1210 (first amplifier) is greater than or equal to the reference voltage V_{ref} (first reference voltage), the comparator unit 1311a (first comparator unit) outputs, to the emitter of the transistor Q40 (first transistor), the signal RF31 (first output signal) which is in line with the difference between the signal level and the reference voltage V_{ref} (first reference voltage). When the signal level of the signal RF22 outputted from the second final-stage amplifier 1220 (second amplifier) is greater than or equal to the reference voltage V_{ref} (second reference voltage), the comparator unit 1312a (second comparator unit) outputs, to the emitter of the transistor Q42 (second transistor), the signal RF32 (second output signal) which is in line with the difference between the signal level and the reference voltage V_{ref} (second reference voltage). Thus, the protection circuit 1300a, which is formed of the differential circuits, causes leaking odd-order harmonic components to cancel each other out, achieving the suppression of the influence from the leakage on the circuit. In addition, the protection circuit 1300a may be compatible with the differential final-stage amplifier 1200.
<8> In the protection circuit according to <7>, the comparator unit 1311b of the protection circuit 1300b includes the transistor Q12 (ninth transistor) which receives, at its collector, the signal RF21 outputted from the first final-stage amplifier 1210 (first amplifier) and which is electrically connected, at its base, to the emitter of the transistor Q42 (second transistor). The comparator unit 1312b includes the transistor Q14 (tenth transistor) which receives, at its collector, the signal RF22 outputted from the second final-stage amplifier 1220 (second amplifier) and which is electrically connected, at its base, to the emitter of the transistor Q40 (first transistor). Thus, when an instantaneous upper-peak voltage at the collector of the differential final-stage amplifier 1200 is greater than or equal to the reference voltage V_{ref} and an instantaneous lower-peak voltage at the collector of the differential final-stage amplifier 1200 approaches 0 V, the protection circuit 1300b may output the control signal D_{cont} at a higher rate, achieving more reliable suppression of the gain of the power amplifier circuit 1000.
<9> In the protection circuit according to any one of <1> to <8>, the power amplifier circuit 1000b (amplifier circuit) is a circuit including a carrier amplifier circuit, which is formed of at least one of the carrier amplifiers 1120 and 1130, and a peak amplifier circuit, which is formed of at least one of the peak amplifiers 1140 and 1150. The comparator unit 1310 outputs, from its output terminal, an output signal which is in line with the difference between the reference voltage V_{ref} and the maximum of the signal level of the signal RF20 outputted from the final-stage carrier amplifier 1130 (predetermined carrier amplifier) among the at least one carrier amplifier of the carrier amplifier circuit. The detection unit 1330 outputs the control signal D_{cont} to a predetermined circuit (in this example, at least any of the bias circuit 1111, the bias circuit 1121, and the bias circuit 1131 illustrated in FIG. 3, or an attenuator which is not illustrated) which is capable of reducing the gain of the carrier amplifier circuit. Thus, when the final-stage carrier amplifier 1130 is saturated or starts to be saturated, the power amplifier circuit 1000b decreases the bias of the final-stage carrier amplifier 1130 at an appropriate time, achieving the suppression of the gain of the power amplifier circuit 1000.

The embodiment described above is intended to facilitate understanding of the present disclosure, and is not intended to be construed as limiting the present disclosure. The present disclosure may be changed or improved without departing from the gist thereof, and the present disclosure encompasses its equivalents. That is, embodiments obtained by those skilled in the art appropriately changing the design of the embodiment are also encompassed in the scope of the present disclosure, as long as they have features of the present disclosure. The devices included in the embodiment and their layout are not limited to illustrated ones, and may be changed appropriately.
1000 power amplifier circuit
1100 driver-stage amplifier
1200 final-stage amplifier
1300 protection circuit
1310 comparator unit
1320 DC blocking unit
1330 detection unit
1340 amplification unit

1. A protection circuit comprising:
in a power amplifier circuit comprising at least one amplifier,
a comparator that is configured to, when a signal level of a signal outputted from a predetermined one of the at least one amplifiers is greater than or equal to a reference voltage, output an output signal which is in line with a difference between the signal level and the reference voltage from an output terminal of the comparator;
a DC blocking circuit that is electrically connected at a first terminal to the output terminal of the comparator, and that is configured to output a signal obtained by blocking a DC component of the output signal from a second terminal of the DC blocking circuit; and
a detector that is electrically connected at an input terminal thereof, to the second terminal of the DC blocking circuit, and that is configured to outputs, from an output terminal thereof to a predetermined circuit configured to reduce gain of the power amplifier circuit, a control signal which is in line with the signal level of the signal outputted from the predetermined amplifier.

2. The protection circuit according to claim 1, further comprising:
an amplifier that is electrically connected, at an input terminal thereof, to the output terminal of the comparator, and that is electrically connected, at an output terminal thereof, to the first terminal of the DC blocking circuit.

3. The protection circuit according to claim 2,
wherein the amplifier comprises a differential circuit comprising:
a first transistor that receives the output signal at an emitter or source thereof, and
a second transistor that is electrically connected to a reference potential at an emitter or source thereof,
wherein the DC blocking circuit comprises:
a first capacitor that is electrically connected, at a first terminal thereof, to a collector or drain of the first transistor, and
a second capacitor that is electrically connected, at a first terminal thereof, to a collector or drain of the second transistor, and
wherein the detector comprises:
a third transistor that is electrically connected, at a base or gate thereof, to a second terminal of the first capacitor, and
a fourth transistor that is electrically connected, at a base or gate thereof, to a second terminal of the second capacitor.

4. The protection circuit according to claim 1, wherein the comparator comprises:
a plurality of diodes or a plurality of diode-connected transistors that are electrically connected, at a first end thereof, to an input terminal that receives the signal outputted from the predetermined amplifier, and that are electrically connected to a reference potential at a second end thereof, and
a fifth transistor that is connected, in a current mirror configuration, to any of the plurality of diodes or any of the plurality of diode-connected transistors, and that is electrically connected, at a collector or drain thereof, to the first terminal of the DC blocking circuit.

5. The protection circuit according to claim 1,
wherein the comparator comprises:
a plurality of diodes or a plurality of diode-connected transistors that are electrically connected, at a first end thereof, to an input terminal that receives a signal outputted from the predetermined amplifier, and that are electrically connected to a reference potential at a second end thereof, and
a fifth transistor that is connected, in a current mirror configuration, to any of the plurality of diodes or any of the plurality of diode-connected transistors,
wherein the protection circuit further comprises an amplifier comprising a sixth transistor electrically connected, at an emitter or source thereof, to a collector or drain of the fifth transistor,
wherein the DC blocking circuit is electrically connected, at the first terminal thereof, to a collector or drain of the sixth transistor, and
wherein the detector comprises a seventh transistor electrically connected, at a base or gate thereof, to the second terminal of the DC blocking circuit.

6. The protection circuit according to claim 3, wherein the comparator comprises an eighth transistor that receives, at a collector or drain thereof, the signal outputted from the predetermined amplifier, and that is electrically connected, at a base or gate thereof, to the emitter or source of the second transistor.

7. The protection circuit according to claim 3,
wherein the predetermined amplifier of the power amplifier circuit a differential circuit comprising a first amplifier and a second amplifier,
wherein the comparator comprises:
a first comparator that is configured to, when a signal outputted from the first amplifier has a first signal level greater than or equal to a first reference voltage, output a first output signal which is in line with a difference between the first signal level and the first reference voltage to the emitter or source of the first transistor, and
a second comparator that is configured to, when a signal outputted from the second amplifier has a second signal level greater than or equal to a second reference voltage, output a second output signal which is in line with a difference between the second signal level and the second reference voltage to the emitter or source of the second transistor.

8. The protection circuit according to claim 7,
wherein the first comparator comprises a ninth transistor that receives, at a collector or drain thereof, the signal outputted from the first amplifier, and that is electrically connected, at a base or gate thereof, to the emitter or source of the second transistor, and
wherein the second comparator comprises a tenth transistor that receives, at a collector or drain thereof, the signal outputted from the second amplifier, and that is electrically connected, at a base or gate thereof, to the emitter or source of the first transistor.

9. The protection circuit according to claim 1,
wherein the power amplifier circuit is a circuit comprising a carrier amplifier circuit and a peak amplifier circuit, the carrier amplifier circuit comprising at least one carrier amplifier, the peak amplifier circuit comprising at least one peak amplifier,
wherein the comparator is configured to output, from the output terminal thereof, an output signal which is in line with a difference between a reference voltage and a maximum of a signal level of a signal outputted from one of the carrier amplifiers of the carrier amplifier circuit, and
wherein the detector is configured to output the control signal to a predetermined circuit configured to reduce a gain of the carrier amplifier circuit.
